(19) United States
(12) Patent Application Publication
(10) Pub. No.: US 2018/0323360 A1
(43) Pub. Date: Nov. 8, 2018

(54) ZINTL-PHASE THERMOELECTRIC CONVERSION MATERIAL

(71) Applicant: Panasonic Intellectual Property Management Co., Ltd., Osaka (JP)

(72) Inventors: TSUTOMU KANNO, Kyoto (JP); HIROMASA TAMAKI, Osaka (JP); HIROKI SATO, Nara (JP)

(21) Appl. No.: 15/838,106

(22) Filed: Dec. 11, 2017

(30) Foreign Application Priority Data
May 8, 2017 (JP) 2017-092581

(51) Int. Cl. H01L 35/16; C04B 35/547

(52) U.S. Cl. CPC H01L 35/16; C04B 2235/786; C04B 2235/666; C04B 35/547

(57) ABSTRACT

The present invention provides a Zintl-phase thermoelectric conversion material represented by the chemical formula (I):

Mg₃₊ₘ₋ₐAₐB_{2-c-e}C_{c}Eₑ (I)
where
A represents at least one selected from the group consisting of Ca, Sr, Ba, Nb, Zn, and Al;
B represents at least one selected from the group consisting of Sb and Bi;
C represents at least one selected from the group consisting of Mn, Si, and Cr;
E represents at least one selected from the group consisting of Se and Te;
m is not less than −0.1 and not more than 0.4;
a is not less than 0 and not more than 0.1;
c is not less than 0 and not more than 0.1;
e is not less than 0.001 and not more than 0.06; and
the Zintl-phase thermoelectric conversion material has a La₂O₃ crystal structure and an average grain size of not less than 3 micrometers and not more than 70 micrometers.

### BACKGROUND

### 1. Technical Field

The present invention relates to a thermoelectric conversion material.

### 2. Description of the Related Art

NPL1 discloses a thermoelectric conversion material represented by the chemical formula Mg_{3+δ}Sb_{1.5}Bi_{0.49}Te_{0.01} (δ=0.1, 0.2, or 0.3) and a fabrication method thereof.

NPL2 discloses a thermoelectric conversion material represented by the chemical formula Mg₃Sb_{1.5-0.5x}Bi_{0.5-0.5x}Teₓ(x=0.04, 0.05, 0.08, or 0.20) and a fabrication method thereof.

NPL3 discloses a thermoelectric conversion material represented by the chemical formulas Mg_{3.2}Sb_{1.5}Bi_{0.5}Teₓ(x=0.002, 0.004, 0.006, 0.008, or 0.010) and Mg_{3.2-x}NbₓSb_{1.5}Bi_{0.49}Te_{0.01}(x=0, 0.01, 0.05, 0.1, or 0.15) and a fabrication method thereof.

### CITATION LIST

NPL1: H. Tamaki et al., “Isotropic Conduction Network and Defect Chemistry in Mg_{3+δ}Sb₂-Based Layered Zintl Compounds with High Thermoelectric Performance”, Advanced Materials, Vol. 28, Issue 46, pp. 10182-10187 (2016)

NPL2: J. Zhang et al., “Discovery of high-performance low-cost n-type Mg₃Sb₂-based thermoelectric materials with multi-valley conduction bands”, Nature Communications, Vol. 8, Article number 13901 (2017)

NPL3: S. Jing et al., “Tuning the carrier scattering mechanism to effectively improve the thermoelectric properties”, Energy and Environmental Science (2017)

### SUMMARY

An object of the present invention is to provide a thermoelectric conversion material having a high performance at a temperature of approximately 200 degrees Celsius.

The present invention provides a Zintl-phase thermoelectric conversion material represented by the following chemical formula (I):

Mg₃₊ₘ₋ₐAₐB_{2-c-e}C_{c}Eₑ (I)
where
the element A represents at least one selected from the group consisting of Ca, Sr, Ba, Nb, Zn, and Al;
the element B represents at least one selected from the group consisting of Sb and Bi;
the element C represents at least one selected from the group consisting of Mn, Si, and Cr;
the element E represents at least one selected from the group consisting of Se and Te;
the value of m is not less than −0.1 and not more than 0.4;
the value of a is not less than 0 and not more than 0.1;
the value of c is not less than 0 and not more than 0.1;
the value of e is not less than 0.001 and not more than 0.06;
the Zintl-phase thermoelectric conversion material has a La₂O₃ crystal structure; and
the Zintl-phase thermoelectric conversion material has an average grain size of not less than 3 micrometers and not more than 70 micrometers.

The present invention provides a thermoelectric conversion material having a high performance at a temperature of approximately 200 degrees Celsius.

### BRIEF DESCRIPTION OF THE DRAWINGS

FIG. 1 shows a schematic view of a La₂O₃ crystal structure.

FIG. 2A is a graph showing a result of an X-ray diffraction analysis of the Zintl-phase thermoelectric conversion material according to the inventive example 1.

FIG. 2B is a graph showing a simulation result of an X-ray diffraction spectrum of a La₂O₃-type crystalline structure.

FIG. 3A shows a SEM observation image in the inventive example 1.

FIG. 3B shows a SEM observation image in the comparative example 1.

FIG. 4 is a graph showing a relation between a temperature and a thermoelectric conversion performance index ZT of the inventive example 1 and the comparative example 1.

### DETAILED DESCRIPTION OF THE EMBODIMENT

Hereinafter, the embodiment of the present invention will be described in detail.

The Zintl-phase thermoelectric conversion material according to the present invention is a polycrystal represented by the following chemical formula (I):

Mg₃₊ₘ₋ₐAₐB_{2-c-e}C_{c}Eₑ (I)
where
the element A represents at least one selected from the group consisting of Ca, Sr, Ba, Nb, Zn, and Al;
the element B represents at least one selected from the group consisting of Sb and Bi;
the element C represents at least one selected from the group consisting of Mn, Si, and Cr;
the element E represents at least one selected from the group consisting of Se and Te;
the value of m is not less than −0.1 and not more than 0.4;
the value of a is not less than 0 and not more than 0.1;
the value of c is not less than 0 and not more than 0.1;
the value of e is not less than 0.001 and not more than 0.06.
The Zintl-phase thermoelectric conversion material has a La₂O₃ crystal structure.
The Zintl-phase thermoelectric conversion material has an average grain size of not less than 3 micrometers and not more than 70 micrometers. Desirably, the value of m is not less than −0.05 and not more than 0.3, the average grain size is not less than 3 micrometers and not more than 30 micrometers, and the value of e is not less than 0.005 and not more than 0.03.

The value of a may be 0. Therefore, the Zintl-phase thermoelectric conversion material according to the present invention need not contain the element A. Similarly, the value of c may be 0. Therefore, the Zintl-phase thermoelectric conversion material according to the present invention need not contain the element C. Furthermore, the following mathematical formula (III) may be satisfied.

a=c=0 (III)

Therefore, the Zintl-phase thermoelectric conversion material according to the present invention may contain neither the element A nor the element C.

On the other hand, the Zintl-phase thermoelectric conversion material according to the present invention must contain the element Mg, the element B, and the element E.

The Zintl-phase thermoelectric conversion material according to the present invention is polycrystalline and has an average grain size of not less than 3 micrometers and not more than 70 micrometers.

As well known in the technical field of thermoelectric conversion materials, performance of a thermoelectric conversion material is represented by a thermoelectric conversion performance index ZT, which is represented by the following mathematical formula (IV)

ZT=S²σT/K (IV)

where

S represents Seebeck effect,

σ represents electrical conductivity,

k represents thermal conductivity, and

T represents absolute temperature T.

As demonstrated in the inventive examples which will be described later, the average grain size of not less than 3 micrometers and not more than 70 micrometers improves the thermoelectric conversion performance index ZT at a temperature of approximately 200 degrees Celsius remarkably.

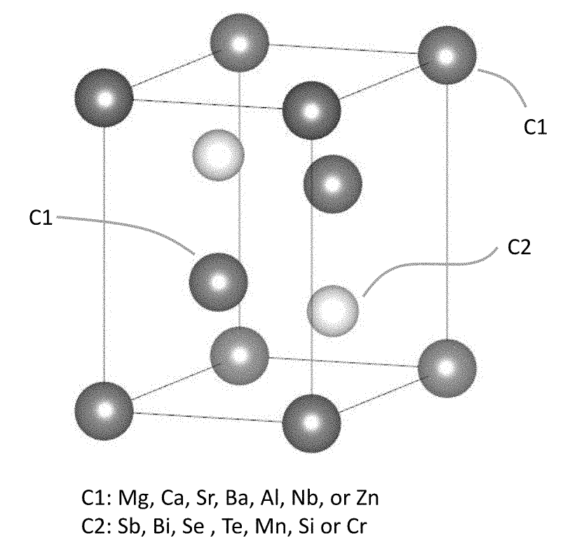

The Zintl-phase thermoelectric conversion material according to the present invention has a La₂O₃ crystal structure. FIG. 1 shows a schematic view of the La₂O₃ crystalline structure.

(Fabrication Method)

Hereinafter, an example of the fabrication method of the Zintl-phase thermoelectric conversion material according to the present invention will be described. First, an antimony-bismuth alloy is provided by melting antimony and bismuth by an arc melting method at a temperature of 1,000 degrees Celsius-1,500 degrees Celsius. Then, the antimony-bismuth alloy, magnesium powder, and tellurium powder are put in a crucible. The crucible is heated to a temperature of 800 degrees Celsius-1,500 degrees Celsius in an electric furnace to provide an aggregated MgSbBiTe precursor alloy.

It is desirable that the crucible is heated in an inert gas atmosphere such as argon or helium to prevent the materials from being oxidized.

Elements may scatter out of the crucible by evaporation during the period of heating in the crucible. Therefore, the molar ratio of the provided MgSbBiTe precursor alloy seldom accords with the molar ratio of the starting materials. The MgSbBiTe precursor alloy is ground and subjected to spark plasma sintering to provide a crystal of MgSbBiSe. In this way, the Zintl-phase thermoelectric conversion material formed of the crystal of MgSbBiSe is provided.

Furthermore, in a case where other elements (i.e., Ca, Sr, Ba, Nb, Zn, Yb, Al, Cr, or Se) are contained, the Zintl-phase thermoelectric conversion material according to the present invention can be provided in a similar way. In addition, the arc melting may be omitted. In this case, the starting materials Mg, Sb, Bi, and Te which have been put in the crucible are heated at a temperature of 800 degrees Celsius-1,500 degrees Celsius in an electric furnace in an inert gas atmosphere to provide the MgSbBiTe precursor alloy.

In the electic furnace, not only resistance heating but also heating with an infrared lump and induction heating with radio frequencey radiation may be used. When the infrare lump or the induction heating is used, it is desirable that the crucible is formed of a material having a property to absorb infrared or radio frequencey radiation and to convert into heat efficiently. An example of such a material of the crucible is carbon or SiC. However, since the starting materials themselves absorb infrared or radio frequencey radiation in some extent, the material of the crucible is not limited. An crucible formed of a comparatively inexpensive material such as alumina may be used.

The precursor alloy can be fabricated with a ball mill in an inert gas atmosphere. In this case, the fabrication and the grinding of the precursor alloy can be conducted concurrently.

The precursor alloy powder is sintered to provide the Zintl-phase thermoelectric conversion material according to the present invention. In the sintering, an ordinal method such as a spark plasma sintering method or a hot-press method may be employed. [0022]

The average grain size of the Zintl-phase thermoelectric conversion material according to the present invention can be controlled by some ways. For example, the sintering temperature may be increased or still-standing period may be extended to promote grain growth. As a result, the average grain size is increased. In addition, before the sintering, the powders may be classified with a filter to fabricate a Zintl-phase thermoelectric conversion material having a desired average grain size.

### EXAMPLES

The present invention will be described in more detail with reference to the following examples.

### Inventive Examples 1, 2A, 2B, 3A, and 3B & Comparative Examples 1, 2A, and 2 B

### Inventive Examples 1

(Fabrication Method)

In the inventive example 1, a Zintl-phase thermoelectric conversion material represented by the chemical formula Mg_{3.2}Sb_{1.5}Bi_{0.49}Te_{0.01} and having a La₂O₃ crystal structure was fabricated as below.

First, magnesium powder (2.00 grams), antimony powder (4.67 grams) and bismuth powder (2.63 grams), and tellurium powder (0.033 grams) were prepared as starting materials in a glove box filled with argon. Then, prepared powders were put into a stainless ball mill container (inner volume: 80 milliliters) together with thirty stainless balls (diameter: 10 millimeters). The ball mill container was sealed in the glove box.

Then, the ball mill container containing the staring materials was taken out of the glove box. The starting materials contained in the ball mill container were ground at a rotation rate of 400 rpm for a total time of 4 hours with a planetary ball mill machine (purchased from Fritsch Japan Co., Ltd., trade name: Pulverisette 6).

Subsequently, the ball mill container was unsealed in the glove box. The powder contained therein was taken out. A carbon die (namely, a sintering mold) having an inner diameter of 10 millimeters was filled with the powder. The weight of the powder with which the die was filled was approximately 2 grams.

The powder was sintered by a spark plasma sintering method (hereinafter, referred to as “SPS method”) as below. A chamber of the SPS sintering machine was filled with an argon gas. An electric current was applied to the powder with which the cylindrical die was filled, while a pressure of 50 MPa was applied to the powder. In this way, the powder was heated. The temperature of the material (i.e., powder) with which the cylindrical die was filled was increased at a rate of approximately 50 degrees Celsius/minute. The temperature of the material was maintained at 900 degrees Celsius for five minutes. Then, the temperature of the material was maintained at 600 degrees Celsius for thirty minutes. Finally, the temperature of the material was cooled to room temperature. In this way, the Zintl-phase thermoelectric conversion material according to the inventive example 1 was provided as a dense sintered body.

### Comparative example 1

Apart from the above, the Zintl-phase thermoelectric conversion material according to the comparative example 1 was provided similarly to that of the inventive example 1, except for the sintering temperature in the SPS method. In particular, in the comparative example 1, during the sintering process of the SPS method, the temperature of the material was increased at a rate of 50 degrees Celsius from room temperature to 600 degrees Celsius. Then, the temperature of the material was maintained at 600 degrees Celsius for 30 minutes. Finally, the temperature of the material was cooled to room temperature.

### Inventive examples 2A, 2B, 3A, and 3B & Comparative examples 2A and 2B

In the above examples, a sintered body represented by the chemical formula Mg_{3.2}Sb_{1.5}Bi_{0.49}Te_{0.01} was fabricated in accordance with the following process by a radio frequency radiation melting method and the SPS method.

First, magnesium powder (4.00 grams), antimony powder (9.67 grams) and bismuth powder (5.26 grams), and tellurium powder (0.066 grams) were put into a carbon crucible. Then, these powders were melt by the radio frequency radiation heating method at a temperature of 800-1,000 degrees Celsius in an argon atmosphere. The melted material was cooled to room temperature. In this way, an aggregated ingot was provided.

The ingot was ground with a mortar in a glove box filled with argon. The provided powder was filtered with a filter having openings of 100 micrometers each and a filter having openings of 50 micrometers each. As a result, the following three kinds (I)-(III) of powders were provided.
(I) powder which passed through the filter having the openings of 50 micrometers each;
(II) powder which passed through the filter having the openings of 100 micrometers each, however, which did not passed through the filter having the openings of 50 micrometers each; and
(III) powder which did not passed through the filter having the openings of 100 micrometers each.

Three carbon dies (namely, sintering molds) each having an inner diameter of 10 millimeters was filled respectively with these three kinds of the powders (I)-(III). The weight of the powder with which each die was filled was approximately 1 gram-1.5 grams.

Half amounts of these three powders were sintered in an argon atmosphere by the SPS method in the same condition as that of the inventive example 1. In this way, the Zintl-phase thermoelectric conversion materials according to the inventive examples 2A and 3A and the comparative example 2A were provided from the powders (I), (II), and (III), respectively.

The other half amounts of these three powders were also sintered in an argon atmosphere by the SPS method in the same condition as that of the comparative example 1. In this way, the Zintl-phase thermoelectric conversion materials according to the inventive examples 2B and 3B and the comparative example 2B were provided from the powders (I), (II), and (III), respectively.

(Identification of Composition Ratio)

The chemical compositions of the thus-provided Zintl-phase thermoelectric conversion materials were analyzed by an inductively coupled plasma atomic emission spectroscopy method (hereinafter, referred to as “ICP-AES”). Table 1 shows chemical composition of the starting material and the provided material according to each example. In all Tables included in the present specification, “I.E.” and “C.E.” mean “Inventive Example” and “Comparative Example”, respectively. As is clear from Table 1, the chemical composition of each of the provided Zintl-phase thermoelectric conversion materials is the same as that of the starting material.

TABLE 1

| | Composition of | Composition of provided |
|---|---|---|
| | Starting Material | Zintl-phase thermoelectric |
| | Mg:Sb:Bi:Te | conversion material |
| I.E. 1 | 3.2:1.5:0.49:0.01 | Mg_{3.21}Sb_{1.52}Bi_{0.47}Te_{0.010} |
| C.E. 1 | 3.2:1.5:0.49:0.01 | Mg_{3.22}Sb_{1.50}Bi_{0.49}Te_{0.009} |
| I.E. 2A | 3.2:1.5:0.49:0.01 | Mg_{3.19}Sb_{1.50}Bi_{0.49}Te_{0.010} |
| I.E. 2B | 3.2:1.5:0.49:0.01 | Mg_{3.20}Sb_{1.49}Bi_{0.50}Te_{0.011} |
| I.E. 3A | 3.2:1.5:0.49:0.01 | Mg_{3.15}Sb_{1.48}Bi_{0.51}Te_{0.009} |
| I.E. 3B | 3.2:1.5:0.49:0.01 | Mg_{3.18}Sb_{1.51}Bi_{0.48}Te_{0.012} |
| C.E. 2A | 3.2:1.5:0.49:0.01 | Mg_{3.20}Sb_{1.49}Bi_{0.50}Te_{0.008} |
| C.E. 2B | 3.2:1.5:0.49:0.01 | Mg_{3.16}Sb_{1.50}Bi_{0.49}Te_{0.009} |

(Observation of Crystal Structure)

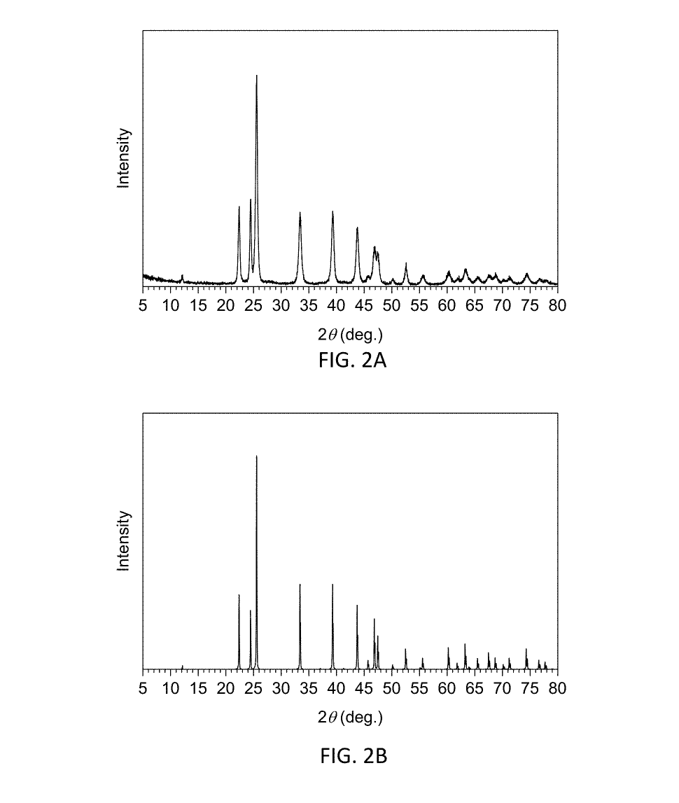

The Zintl-phase thermoelectric conversion material according to the inventive example 1 was subjected to an X-ray diffraction analysis. FIG. 2A is a graph showing the analysis result thereof. FIG. 2B is a graph of an X-ray diffraction analysis showing a simulation result of an X-ray diffraction spectrum of a La₂O₃-type crystalline structure (or CaAl₂Si₂-type crystalline structure) having an a-axis constant, a b-axis constant, and a c-axis constant respectively having 0.458 nanometers, 0.458 nanometers, and 0.727 nanometers. The peak positions included in the X-ray diffraction spectrum in the inventive example 1 accord with those of FIG. 2B. Therefore, FIG. 2A reveals that the Zintl-phase thermoelectric conversion material according to the inventive example 1 has a La₂O₃-type crystalline structure. The present inventors confirmed that each of the Zintl-phase thermoelectric conversion materials according to all the inventive and comparative examples has a La₂O₃-type crystalline structure, since each of them has a similar X-ray diffraction spectrum result.

(Measurement of Average Grain Size)

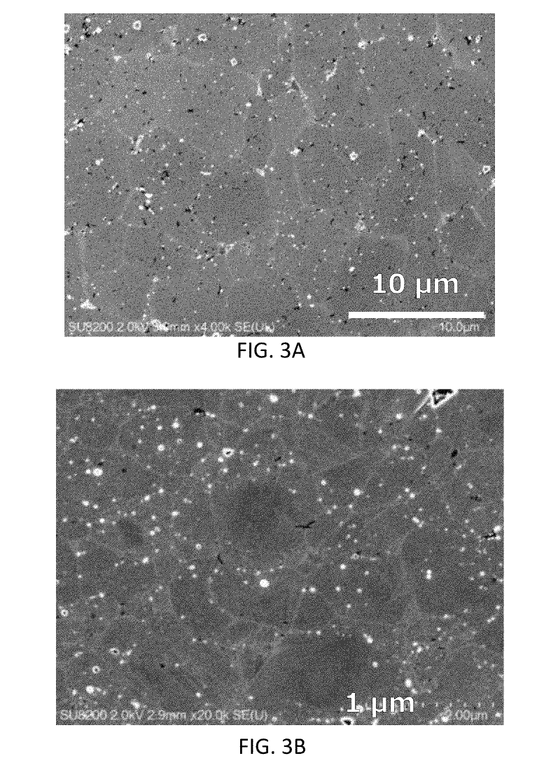

The Zintl-phase thermoelectric conversion material according to the inventive example 1 was subjected to an analysis using a secondary electron microscope (hereinafter, referred to as “SEM”). Before the SEM analysis, the Zintl-phase thermoelectric conversion material according to the inventive example 1 was polished with a polishing paper and an argon beam. FIG. 3A shows a SEM observation image. Grains separated by grain boundaries were observed clearly. Similarly, FIG. 3B shows a SEM observation image in the comparative example 1.

The average grain size used in the present specification is defined as below. First, a grain number N is counted in the SEM image such as FIG. 3A or FIG. 3B. In the counting, a grain observed partially at the edge of the SEM image is counted as 0.5 conveniently. The average grain size, which may be referred to as “AGS” hereinafter, is defined in accordance with the following mathematical formula (V).

AGS={4A/(π·N)}^{1/2} (V)

where

A is an area of an visual field of the SEM image;

N is a grain number; and

π is a ratio of the circumference of a circle to its diameter (i.e., Pi).

The mathematical formula (V) is an approximate formula representing a diameter of a grain under an assumption that the grain has a shape of a perfect sphere and that a cross section including the center of the grain is observed in the SEM image. Actually, for example, as is clear from FIG. 3A and FIG. 3B, since the grain has an indefinite shape and does not have a shape of a perfect sphere, the average grain size calculated on the basis of the mathematical formula (V) is not always equal to a diameter of the grain. In the present specification, the value calculated on the basis of the mathematical formula (V) is defined as the average grain size conveniently. Hereinafter, using the above value, the example will be described and the claims should be interpreted.

When the average grain size is calculated, it is desirable to employ a SEM image including 20 or more grains in the view field in light of the suppression of statistical errors. It is more desirable that the average grain size is calculated employing plural parts included in one SEM image.

The present inventors employed FIG. 3A and other SEM images each having different view fields to calculate the average grain size in the inventive example 1. As a result, in the inventive example 1, the average grain size was 6.2 micrometers. Furthermore, the present inventors employed FIG. 3B and other SEM images each having different view fields to calculate the average grain size in the comparative example 1. As a result, in the comparative example 1, the average grain size was 0.95 micrometers.

(Thermoelectric Conversion Performance)

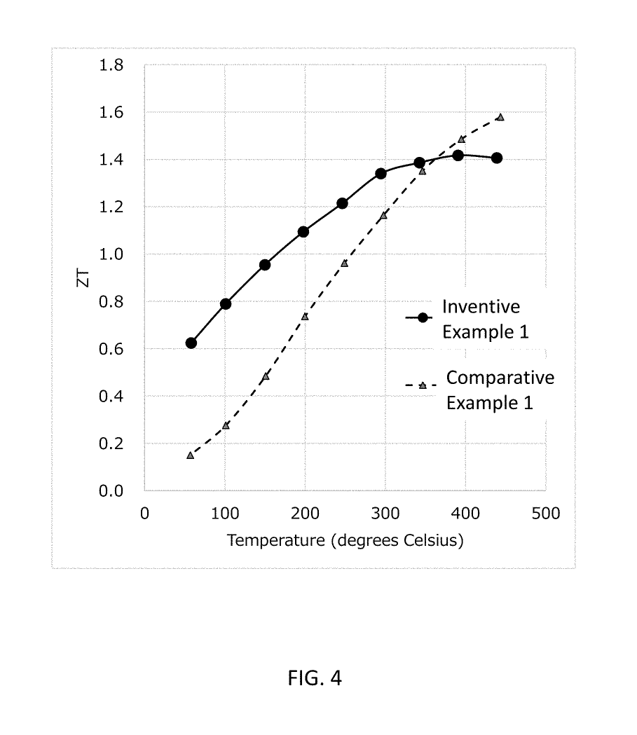

FIG. 4 is a graph showing a relation between a temperature and a thermoelectric conversion performance index ZT in the inventive example 1 and the comparative example 1. For the detail of the calculation method of the thermoelectric conversion performance index ZT, see U.S. patent applications Ser. Nos. 14/847, 321, 14/847,362, and 14/718,491, the contents of which are incorporated herein by reference.

The Zintl-phase thermoelectric conversion material according to the inventive example 1 has a significantly higher ZT value than those of the comparative examples within the temperature range between room temperature and approximately 300 degrees Celsius. In the comparison of the ZT value of the inventive example 1 to that of the comparative example 1 at a temperature of approximately 200 degrees Celsius, which represents a general performance value, the ZT value of the inventive example 1 is 1.1 whereas the ZT value of the comparative example 1 is 0.7. In other words, at the temperature of approximately 200 degrees Celsius, the Zintl-phase thermoelectric conversion material according to the inventive example 1 has an approximately 1.6 times higher ZT value than that of the comparative example 1. Typically, the electric power generation efficiency is higher, as the ZT value on average is higher within an operation temperature range (i.e., a temperature range from low temperature to high temperature). As above described, the electric power generation efficiency of the Zintl-phase thermoelectric conversion material according to the present invention is improved at a temperature of not more than 300 degrees Celsius, compared to conventional thermoelectric conversion materials.

Table 2 shows the average grain size, SPS sintering temperature, the thermoelectric conversion performance index ZT at a temperature of 200 degrees Celsius of the present inventive examples and comparative examples. When the average grain size falls within the range of not less than 6.2 micrometers and not more than 72.1 micrometers, the thermoelectric conversion performance index ZT at a temperature of 200 degrees Celsius is a high value of not less than 1.0. On the other hand, out of the above range (i.e., when the average grain size is less than 6.2 micrometers or more than 72.1 micrometers), the ZT value is low. When the SPS sintering temperature is higher, the average grain size tends to be increased more; however, there was not a direct relation between the SPS sintering temperature and the thermoelectric conversion performance index ZT at a temperature of 200 degrees Celsius.

TABLE 2

| | | | Thermoelectric |
|---|---|---|---|
| | | | conversion performance |
| | Average | SPS Sintering | index ZT at a |
| | Grain | Temperature | temperature of |
| | Size | (degrees Celsius) | 200 degrees Celsius |
| I.E. 1 | 6.2 | 900 | 1.1 |
| C.E. 1 | 0.95 | 600 | 0.7 |
| I.E. 2A | 34.2 | 900 | 1.2 |
| I.E. 2B | 21.7 | 600 | 1.1 |
| I.E. 3A | 72.1 | 900 | 1.0 |
| I.E. 3B | 58.9 | 600 | 1.1 |
| C.E. 2A | 92.6 | 900 | 0.4 |
| C.E. 2B | 88.9 | 600 | 0.3 |

### Inventive Examples 4A-7C & Comparative Examples 3A-7B, 7C, and 7D

In the present examples, the Zintl-phase thermoelectric conversion materials represented by the chemical formula Mg_{3.0}Sb_{1.7}Bi_{0.3-e}Eₑ were fabricated in similar ways to those of the inventive examples 1-3. In the present examples, E is Te. The value of e of each of the provided Zintl-phase thermoelectric conversion materials was 0.9-1.1 times as high as that of the starting composition.

Table 3 shows the element E, the value of e, the average grain size, and the thermoelectric conversion performance index ZT at a temperature of 200 degrees Celsius of the present inventive examples and comparative examples. In Table 3, note that E is Te. The thermoelectric conversion performance index ZT at a temperature of 200 degrees Celsius is significantly improved, when the following requirements (I) and (II) are satisfied.

(I) the value of e is not less than 0.001 and not more than 0.06.

(II) the average grain size is approximately not less than 3 micrometers and not more than 70 micrometers.

On the other hand, when the value of e is less than 0.001 or more than 0.06, the thermoelectric conversion performance index ZT at a temperature of 200 degrees Celsius is low, regardless of the value of the average grain size.

TABLE 3

| | | | | Thermoelectric |
|---|---|---|---|---|
| | | | | conversion performance |
| | | | | index ZT at a |
| | | | | temperature of |
| | Element E | Value of e | Grain Size | 200 degrees Celsius |
| C.E. 3A | Te | 0.0005 | 6.8 | 0.1 |
| C.E. 3B | Te | 0.0005 | 57.2 | 0.2 |
| C.E. 4A | Te | 0.001 | 1.8 | 0.4 |
| I.E. 4A | Te | 0.001 | 3.2 | 0.7 |
| I.E. 4B | Te | 0.001 | 25.4 | 0.8 |
| I.E. 4C | Te | 0.001 | 66.2 | 0.7 |
| C.E. 4B | Te | 0.001 | 81.3 | 0.4 |
| C.E. 5A | Te | 0.005 | 2.2 | 0.3 |
| I.E. 5A | Te | 0.005 | 4.5 | 1.0 |
| I.E. 5B | Te | 0.005 | 28.0 | 1.2 |
| I.E. 5C | Te | 0.005 | 70.7 | 0.8 |
| C.E. 5B | Te | 0.005 | 85.1 | 0.4 |
| C.E. 6A | Te | 0.03 | 0.98 | 0.3 |
| I.E. 6A | Te | 0.03 | 3.3 | 1.1 |
| I.E. 6B | Te | 0.03 | 30.1 | 1.0 |
| I.E. 6C | Te | 0.03 | 63.6 | 0.8 |
| C.E. 6B | Te | 0.03 | 82.3 | 0.6 |
| C.E. 7A | Te | 0.06 | 1.8 | 0.2 |
| I.E. 7A | Te | 0.06 | 5.2 | 0.8 |
| I.E. 7B | Te | 0.06 | 28.9 | 0.8 |
| I.E. 7C | Te | 0.06 | 58.2 | 0.7 |
| C.E. 7B | Te | 0.06 | 75.7 | 0.5 |
| C.E. 7C | Te | 0.08 | 30.0 | 0.3 |
| C.E. 7D | Te | 0.08 | 62.7 | 0.4 |

### Inventive Examples 8A-11C & Comparative Examples 8A-13B

In the present examples, the Zintl-phase thermoelectric conversion materials represented by the chemical formula Mg_{3.1}Sb_{1.3}Bi_{0.7-e}Eₑ were fabricated in similar ways to those of the inventive examples 1-3. In the present examples, E is Se. The value of e of each of the provided Zintl-phase thermoelectric conversion materials was 0.9-1.1 times as high as that of the starting composition.

Table 4 shows the element E, the value of e, the average grain size, and the thermoelectric conversion performance index ZT at a temperature of 200 degrees Celsius of the present inventive examples and comparative examples. In Table 4, note that E is Se. The thermoelectric conversion performance index ZT at a temperature of 200 degrees Celsius is significantly improved, when the following requirements (I) and (II) are satisfied.

(I) the value of e is not less than 0.001 and not more than 0.06.

(II) the average grain size is approximately not less than 3 micrometers and not more than 70 micrometers.

On the other hand, when the value of e is less than 0.001 or more than 0.06, the thermoelectric conversion performance index ZT at a temperature of 200 degrees Celsius is low, regardless of the value of the average grain size.

TABLE 4

| | | | | Thermoelectric |
|---|---|---|---|---|
| | | | | conversion performance |
| | | | | index ZT at a |
| | | | | temperature of |
| | Element E | Value of e | Grain Size | 200 degrees Celsius |
| C.E. 8A | Se | 0.0005 | 4.5 | 0.2 |
| C.E. 8B | Se | 0.0005 | 53.1 | 0.1 |
| C.E. 9A | Se | 0.001 | 1.8 | 0.3 |
| I.E. 8A | Se | 0.001 | 4.2 | 0.8 |
| I.E. 8B | Se | 0.001 | 25.7 | 0.9 |
| I.E. 8C | Se | 0.001 | 65.3 | 0.6 |
| C.E. 9B | Se | 0.001 | 82.0 | 0.3 |
| C.E. 10A | Se | 0.005 | 1.4 | 0.2 |
| I.E. 9A | Se | 0.005 | 6.7 | 1.0 |
| I.E. 9B | Se | 0.005 | 28.2 | 1.1 |
| I.E. 9C | Se | 0.005 | 68.8 | 0.8 |
| C.E. 10B | Se | 0.005 | 76.5 | 0.5 |
| C.E. 11A | Se | 0.03 | 2.4 | 0.4 |
| I.E. 10A | Se | 0.03 | 4.7 | 1.1 |
| I.E. 10B | Se | 0.03 | 25.8 | 1.0 |
| I.E. 10C | Se | 0.03 | 63.0 | 0.9 |
| C.E. 11B | Se | 0.03 | 96.9 | 0.6 |
| C.E. 12A | Se | 0.06 | 1.5 | 0.3 |
| I.E. 11A | Se | 0.06 | 5.6 | 0.8 |
| I.E. 11B | Se | 0.06 | 28.0 | 0.7 |
| I.E. 11C | Se | 0.06 | 68.8 | 0.8 |
| C.E. 12B | Se | 0.06 | 81.0 | 0.4 |
| C.E. 13A | Se | 0.08 | 5.2 | 0.3 |
| C.E. 13B | Se | 0.08 | 43.3 | 0.2 |

### Inventive Examples 12A-14C & Comparative Examples 14A-17B

In the present examples, the Zintl-phase thermoelectric conversion materials represented by the chemical formula Mg_{3.4-a}AₐSb_{1.0}Bi_{0.98}Te_{0.02} were fabricated in similar ways to those of the inventive examples 1-3. In the present examples, A is Ca. The value of a of each of the provided Zintl-phase thermoelectric conversion materials was 0.9-1.1 times as high as that of the starting composition.

Table 5 shows the element A, the value of a, the average grain size, and the thermoelectric conversion performance index ZT at a temperature of 200 degrees Celsius of the present inventive examples and comparative examples. In Table 5, note that E is Ca. The thermoelectric conversion performance index ZT at a temperature of 200 degrees Celsius is significantly improved, when the following requirements (I) and (II) are satisfied.

(I) the value of a is not less than 0 and not more than 0.1.

(II) the average grain size is approximately not less than 3 micrometers and not more than 70 micrometers.

On the other hand, when the value of a is more than 0.1, the thermoelectric conversion performance index ZT at a temperature of 200 degrees Celsius is low, regardless of the value of the average grain size.

TABLE 5

| | | | | Thermoelectric |
|---|---|---|---|---|
| | | | | conversion performance |
| | | | | index ZT at a |
| | | | | temperature of |
| | Element A | Value of a | Grain Size | 200 degrees Celsius |
| C.E. 14A | None | 0 | 1.5 | 0.3 |
| I.E. 12A | None | 0 | 4.3 | 0.7 |
| I.E. 12B | None | 0 | 25.2 | 0.8 |
| I.E. 12C | None | 0 | 64.9 | 0.6 |
| C.E. 14B | None | 0 | 81.4 | 0.2 |
| C.E. 15A | Ca | 0.05 | 1.4 | 0.1 |
| I.E. 13A | Ca | 0.05 | 4.4 | 0.5 |
| I.E. 13B | Ca | 0.05 | 28.2 | 0.6 |
| I.E. 13C | Ca | 0.05 | 68.6 | 0.4 |
| C.E. 15B | Ca | 0.05 | 80.3 | 0.2 |
| C.E. 16A | Ca | 0.1 | 0.5 | 0.1 |
| I.E. 14A | Ca | 0.1 | 3.8 | 0.5 |
| I.E. 14B | Ca | 0.1 | 24.3 | 0.5 |
| I.E. 14C | Ca | 0.1 | 61.0 | 0.3 |
| C.E. 16B | Ca | 0.1 | 75.0 | 0.1 |
| C.E. 17A | Ca | 0.15 | 4.6 | 0.1 |
| C.E. 17B | Ca | 0.15 | 42.1 | 0.1 |

### Inventive Examples 15A-17C & Comparative Examples 18A-21B

In the present examples, the Zintl-phase thermoelectric conversion materials represented by the chemical formula Mg_{3.1-a}AₐSb_{1.9}Bi_{0.08}Se_{0.02} were fabricated in similar ways to those of the inventive examples 1-3. In the present examples, A is Sr. The value of a of each of the provided Zintl-phase thermoelectric conversion materials was 0.9-1.1 times as high as that of the starting composition.

Table 6 shows the element A, the value of a, the average grain size, and the thermoelectric conversion performance index ZT at a temperature of 200 degrees Celsius of the present inventive examples and comparative examples. In Table 6, note that A is Sr. The thermoelectric conversion performance index ZT at a temperature of 200 degrees Celsius is significantly improved, when the following requirements (I) and (II) are satisfied.

(I) the value of a is not less than 0 and not more than 0.1.

(II) the average grain size is approximately not less than 3 micrometers and not more than 70 micrometers.

On the other hand, when the value of a is more than 0.1, the thermoelectric conversion performance index ZT at a temperature of 200 degrees Celsius is low, regardless of the value of the average grain size.

TABLE 6

| | | | | Thermoelectric |
|---|---|---|---|---|
| | | | | conversion performance |
| | | | | index ZT at a |
| | | | | temperature of |
| | Element A | Value of a | Grain Size | 200 degrees Celsius |
| C.E. 18A | None | 0 | 0.5 | 0.1 |
| I.E. 15A | None | 0 | 4.7 | 0.6 |
| I.E. 15B | None | 0 | 34.5 | 0.6 |
| I.E. 15C | None | 0 | 66.8 | 0.5 |
| C.E. 18B | None | 0 | 78.6 | 0.3 |
| C.E. 19A | Sr | 0.05 | 1.7 | 0.1 |
| I.E. 16A | Sr | 0.05 | 5.0 | 0.5 |
| I.E. 16B | Sr | 0.05 | 24.3 | 0.4 |
| I.E. 16C | Sr | 0.05 | 64.5 | 0.3 |
| C.E. 19B | Sr | 0.05 | 87.6 | 0.1 |
| C.E. 20A | Sr | 0.1 | 0.8 | 0.05 |
| I.E. 17A | Sr | 0.1 | 4.3 | 0.3 |
| I.E. 17B | Sr | 0.1 | 32.6 | 0.4 |
| I.E. 17C | Sr | 0.1 | 68.2 | 0.2 |
| C.E. 20B | Sr | 0.1 | 73.1 | 0.1 |
| C.E. 21A | Sr | 0.15 | 6.6 | 0.04 |
| C.E. 21B | Sr | 0.15 | 48.7 | 0.05 |

### Inventive Examples 18A-20C & Comparative Examples 22A-25B

In the present examples, the Zintl-phase thermoelectric conversion materials represented by the chemical formula Mg_{3.3-a}AₐSb_{0.5}Bi_{1.49}Te_{0.01} were fabricated in similar ways to those of the inventive examples 1-3. In the present examples, A is Ba. The value of a of each of the provided Zintl-phase thermoelectric conversion materials was 0.9-1.1 times as high as that of the starting composition.

Table 7 shows the element A, the value of a, the average grain size, and the thermoelectric conversion performance index ZT at a temperature of 200 degrees Celsius of the present inventive examples and comparative examples. In Table 7, note that A is Ba. The thermoelectric conversion performance index ZT at a temperature of 200 degrees Celsius is significantly improved, when the following requirements (I) and (II) are satisfied.

(I) the value of a is not less than 0 and not more than 0.1.

(II) the average grain size is approximately not less than 3 micrometers and not more than 70 micrometers.

On the other hand, when the value of a is more than 0.1, the thermoelectric conversion performance index ZT at a temperature of 200 degrees Celsius is low, regardless of the value of the average grain size.

TABLE 7

| | | | | Thermoelectric |
|---|---|---|---|---|
| | | | | conversion performance |
| | | | | index ZT at a |
| | | | | temperature of |
| | Element A | Value of a | Grain Size | 200 degrees Celsius |
| C.E. 22A | None | 0 | 1.9 | 0.2 |
| I.E. 18A | None | 0 | 3.4 | 0.8 |
| I.E. 18B | None | 0 | 28.7 | 0.7 |
| I.E. 18C | None | 0 | 62.8 | 0.6 |
| C.E. 22B | None | 0 | 82.6 | 0.3 |
| C.E. 23A | Ba | 0.05 | 1.8 | 0.2 |
| I.E. 19A | Ba | 0.05 | 5.1 | 0.5 |
| I.E. 19B | Ba | 0.05 | 29.6 | 0.6 |
| I.E. 19C | Ba | 0.05 | 62.7 | 0.4 |
| C.E. 23B | Ba | 0.05 | 73.4 | 0.2 |
| C.E. 24A | Ba | 0.1 | 0.9 | 0.1 |
| I.E. 20A | Ba | 0.1 | 3.6 | 0.5 |
| I.E. 20B | Ba | 0.1 | 30.9 | 0.4 |
| I.E. 20C | Ba | 0.1 | 64.8 | 0.4 |
| C.E. 24B | Ba | 0.1 | 80.5 | 0.2 |
| C.E. 25A | Ba | 0.15 | 5.8 | 0.1 |
| C.E. 25B | Ba | 0.15 | 48.0 | 0.1 |

### Inventive Examples 21A-23C and Comparative Examples 26A-29B

In the present examples, the Zintl-phase thermoelectric conversion materials represented by the chemical formula Mg_{3.1-a}AₐSb_{1.4}Bi_{0.58}Te_{0.02} were fabricated in similar ways to those of the inventive examples 1-3. In the present examples, A is Nb. The value of a of each of the provided Zintl-phase thermoelectric conversion materials was 0.9-1.1 times as high as that of the starting composition.

Table 8 shows the element A, the value of a, the average grain size, and the thermoelectric conversion performance index ZT at a temperature of 200 degrees Celsius of the present inventive examples and comparative examples. In Table 8, note that A is Nb. The thermoelectric conversion performance index ZT at a temperature of 200 degrees Celsius is significantly improved, when the following requirements (I) and (II) are satisfied.

(I) the value of a is not less than 0 and not more than 0.1.

(II) the average grain size is approximately not less than 3 micrometers and not more than 70 micrometers.

On the other hand, when the value of a is more than 0.1, the thermoelectric conversion performance index ZT at a temperature of 200 degrees Celsius is low, regardless of the value of the average grain size.

TABLE 8

| | | | | Thermoelectric |
|---|---|---|---|---|
| | | | | conversion performance |
| | | | | index ZT at a |
| | | | | temperature of |
| | Element A | Value of a | Grain Size | 200 degrees Celsius |
| C.E. 26A | None | 0 | 1.7 | 0.6 |
| I.E. 21A | None | 0 | 4.2 | 1.0 |
| I.E. 21B | None | 0 | 26.0 | 1.2 |
| I.E. 21C | None | 0 | 61.5 | 0.9 |
| C.E. 26B | None | 0 | 74.9 | 0.7 |
| C.E. 27A | Nb | 0.05 | 2.0 | 0.5 |
| I.E. 22A | Nb | 0.05 | 4.5 | 0.9 |
| I.E. 22B | Nb | 0.05 | 32.2 | 1.1 |
| I.E. 22C | Nb | 0.05 | 69.8 | 0.8 |
| C.E. 27B | Nb | 0.05 | 86.9 | 0.5 |
| C.E. 28A | Nb | 0.1 | 0.8 | 0.5 |
| I.E. 23A | Nb | 0.1 | 6.2 | 1.1 |
| I.E. 23B | Nb | 0.1 | 26.1 | 1.0 |
| I.E. 23C | Nb | 0.1 | 60.2 | 1.0 |
| C.E. 28B | Nb | 0.1 | 78.6 | 0.6 |
| C.E. 29A | Nb | 0.15 | 5.3 | 0.4 |
| C.E. 29B | Nb | 0.15 | 27.0 | 0.3 |

### Inventive Examples 24A-26C & Comparative Examples 30A-33B

In the present examples, the Zintl-phase thermoelectric conversion materials represented by the chemical formula Mg_{2.9}AₐSb_{1.97}Se_{0.03} were fabricated in similar ways to those of the inventive examples 1-3. In the present examples, A is Al. The value of a of each of the provided Zintl-phase thermoelectric conversion materials was 0.9-1.1 times as high as that of the starting composition.

Table 9 shows the element A, the value of a, the average grain size, and the thermoelectric conversion performance index ZT at a temperature of 200 degrees Celsius of the present inventive examples and comparative examples. In Table 9, note that A is Al. The thermoelectric conversion performance index ZT at a temperature of 200 degrees Celsius is significantly improved, when the following requirements (I) and (II) are satisfied.

(I) the value of a is not less than 0 and not more than 0.1.

(II) the average grain size is approximately not less than 3 micrometers and not more than 70 micrometers.

On the other hand, when the value of a is more than 0.1, the thermoelectric conversion performance index ZT at a temperature of 200 degrees Celsius is low, regardless of the value of the average grain size.

TABLE 9

| | | | | Thermoelectric |
|---|---|---|---|---|
| | | | | conversion performance |
| | | | | index ZT at a |
| | | | | temperature of |
| | Element A | Value of a | Grain Size | 200 degrees Celsius |
| C.E. 30A | None | 0 | 2.0 | 0.2 |
| I.E. 24A | None | 0 | 6.2 | 0.8 |
| I.E. 24B | None | 0 | 30.8 | 0.7 |
| I.E. 24C | None | 0 | 86.3 | 0.6 |
| C.E. 30B | None | 0 | 74.5 | 0.3 |
| C.E. 31A | Al | 0.05 | 1.8 | 0.2 |
| I.E. 25A | Al | 0.05 | 3.9 | 0.7 |
| I.E. 25B | Al | 0.05 | 32.4 | 0.6 |
| I.E. 25C | Al | 0.05 | 63.8 | 0.6 |
| C.E. 31B | Al | 0.05 | 82.1 | 0.3 |
| C.E. 32A | Al | 0.1 | 1.6 | 0.1 |
| I.E. 26A | Al | 0.1 | 6.5 | 0.5 |
| I.E. 26B | Al | 0.1 | 28.3 | 0.5 |
| I.E. 26C | Al | 0.1 | 63.7 | 0.4 |
| C.E. 32B | Al | 0.1 | 80.4 | 0.1 |
| C.E. 33A | Al | 0.15 | 3.9 | 0.2 |
| C.E. 33B | Al | 0.15 | 39.5 | 0.1 |

### Inventive Examples 27A-29C & Comparative Examples 34A-37B

In the present examples, the Zintl-phase thermoelectric conversion materials represented by the chemical formula Mg_{3.1}Sb_{0.3}Bi_{1.68-c}C_{c}Te_{0.02} were fabricated in similar ways to those of the inventive examples 1-3. In the present examples, C is Mn. The value of c of each of the provided Zintl-phase thermoelectric conversion materials was 0.9-1.1 times as high as that of the starting composition.

Table 10 shows the element C, the value of c, the average grain size, and the thermoelectric conversion performance index ZT at a temperature of 200 degrees Celsius of the present inventive examples and comparative examples. In Table 10, note that C is Mn. The thermoelectric conversion performance index ZT at a temperature of 200 degrees Celsius is significantly improved, when the following requirements (I) and (II) are satisfied.

(I) the value of c is not less than 0 and not more than 0.1.

(II) the average grain size is approximately not less than 3 micrometers and not more than 70 micrometers.

On the other hand, when the value of c is more than 0.1, the thermoelectric conversion performance index ZT at a temperature of 200 degrees Celsius is low, regardless of the value of the average grain size.

TABLE 10

| | | | | Thermoelectric |
|---|---|---|---|---|
| | | | | conversion performance |
| | | | | index ZT at a |
| | | | | temperature of |
| | Element C | Value of c | Grain Size | 200 degrees Celsius |
| C.E. 34A | None | 0 | 0.6 | 0.3 |
| I.E. 27A | None | 0 | 6.3 | 0.8 |
| I.E. 27B | None | 0 | 34.9 | 0.7 |
| I.E. 27C | None | 0 | 60.6 | 0.6 |
| C.E. 34B | None | 0 | 82.6 | 0.3 |
| C.E. 35A | Mn | 0.05 | 1.1 | 0.2 |
| I.E. 28A | Mn | 0.05 | 5.2 | 0.6 |
| I.E. 28B | Mn | 0.05 | 35.6 | 0.6 |
| I.E. 28C | Mn | 0.05 | 66.7 | 0.4 |
| C.E. 35B | Mn | 0.05 | 89.5 | 0.2 |
| C.E. 36A | Mn | 0.1 | 1.7 | 0.2 |
| I.E. 29A | Mn | 0.1 | 5.3 | 0.6 |
| I.E. 29B | Mn | 0.1 | 32.2 | 0.5 |
| I.E. 29C | Mn | 0.1 | 65.9 | 0.4 |
| C.E. 36B | Mn | 0.1 | 79.3 | 0.2 |
| C.E. 37A | Mn | 0.15 | 5.8 | 0.05 |
| C.E. 37B | Mn | 0.15 | 41.0 | 0.1 |

### Inventive Examples 30A-32C & Comparative Examples 38A-41B

In the present examples, the Zintl-phase thermoelectric conversion materials represented by the chemical formula Mg_{3.3-a}AₐSb_{0.5}Bi_{1.5}Se_{0.03} were fabricated in similar ways to those of the inventive examples 1-3. In the present examples, A is Zn. The value of a of each of the provided Zintl-phase thermoelectric conversion materials was 0.9-1.1 times as high as that of the starting composition.

Table 11 shows the element A, the value of a, the average grain size, and the thermoelectric conversion performance index ZT at a temperature of 200 degrees Celsius of the present inventive examples and comparative examples. In Table 11, note that A is Zn. The thermoelectric conversion performance index ZT at a temperature of 200 degrees Celsius is significantly improved, when the following requirements (I) and (II) are satisfied.

(I) the value of c is not less than 0 and not more than 0.1.

(II) the average grain size is approximately not less than 3 micrometers and not more than 70 micrometers.

On the other hand, when the value of a is more than 0.1, the thermoelectric conversion performance index ZT at a temperature of 200 degrees Celsius is low, regardless of the value of the average grain size.

TABLE 11

| | | | | Thermoelectric |
|---|---|---|---|---|
| | | | | conversion performance |
| | | | | index ZT at a |
| | | | | temperature of |
| | Element A | Value of a | Grain Size | 200 degrees Celsius |
| C.E. 38A | None | 0 | 1.6 | 0.2 |
| I.E. 30A | None | 0 | 6.0 | 0.6 |
| I.E. 30B | None | 0 | 32.7 | 0.5 |
| I.E. 30C | None | 0 | 65.2 | 0.5 |
| C.E. 38B | None | 0 | 78.2 | 0.1 |
| C.E. 39A | Zn | 0.05 | 1.7 | 0.1 |
| I.E. 31A | Zn | 0.05 | 4.5 | 0.4 |
| I.E. 31B | Zn | 0.05 | 30.0 | 0.3 |
| I.E. 31C | Zn | 0.05 | 66.7 | 0.4 |
| C.E. 39B | Zn | 0.05 | 76.8 | 0.1 |
| C.E. 40A | Zn | 0.1 | 1.2 | 0.1 |
| I.E. 32A | Zn | 0.1 | 3.7 | 0.5 |
| I.E. 32B | Zn | 0.1 | 28.8 | 0.5 |
| I.E. 32C | Zn | 0.1 | 65.8 | 0.4 |
| C.E. 40B | Zn | 0.1 | 75.1 | 0.2 |
| C.E. 41A | Zn | 0.15 | 6.8 | 0.1 |
| C.E. 41B | Zn | 0.15 | 24.5 | 0.2 |

### Inventive Examples 33A-35C & Comparative Examples 42A-45B

In the present examples, the Zintl-phase thermoelectric conversion materials represented by the chemical formula Mg_{3.0}Sb_{1.4}Bi_{0.58-c}C_{c}Se_{0.02} were fabricated in similar ways to those of the inventive examples 1-3. In the present examples, C is Si. The value of c of each of the provided Zintl-phase thermoelectric conversion materials was 0.9-1.1 times as high as that of the starting composition.

Table 12 shows the element C, the value of c, the average grain size, and the thermoelectric conversion performance index ZT at a temperature of 200 degrees Celsius of the present inventive examples and comparative examples. In Table 12, note that C is Si. The thermoelectric conversion performance index ZT at a temperature of 200 degrees Celsius is significantly improved, when the following requirements (I) and (II) are satisfied.

(I) the value of c is not less than 0 and not more than 0.1.

(II) the average grain size is approximately not less than 3 micrometers and not more than 70 micrometers.

On the other hand, when the value of c is more than 0.1, the thermoelectric conversion performance index ZT at a temperature of 200 degrees Celsius is low, regardless of the value of the average grain size.

TABLE 12

| | | | | Thermoelectric |
|---|---|---|---|---|
| | | | | conversion performance |
| | | | | index ZT at a |
| | | | | temperature of |
| | Element C | Value of c | Grain Size | 200 degrees Celsius |
| C.E. 42A | None | 0 | 0.9 | 0.5 |
| I.E. 33A | None | 0 | 6.8 | 1.1 |
| I.E. 33B | None | 0 | 26.7 | 1.0 |
| I.E. 33C | None | 0 | 64.9 | 0.8 |
| C.E. 42B | None | 0 | 85.6 | 0.5 |
| C.E. 43A | Si | 0.05 | 1.6 | 0.4 |
| I.E. 34A | Si | 0.05 | 4.3 | 0.8 |
| I.E. 34B | Si | 0.05 | 33.8 | 0.8 |
| I.E. 34C | Si | 0.05 | 63.8 | 0.6 |
| C.E. 43B | Si | 0.05 | 80.2 | 0.3 |
| C.E. 44A | Si | 0.1 | 1.5 | 0.2 |
| I.E. 35A | Si | 0.1 | 6.2 | 0.6 |
| I.E. 35B | Si | 0.1 | 30.5 | 0.7 |
| I.E. 35C | Si | 0.1 | 67.4 | 0.4 |
| C.E. 44B | Si | 0.1 | 76.3 | 0.2 |
| C.E. 45A | Si | 0.15 | 4.3 | 0.3 |
| C.E. 45B | Si | 0.15 | 24.6 | 0.2 |

### Inventive Examples 36A-38C & Comparative Examples 46A-49B

In the present examples, the Zintl-phase thermoelectric conversion materials represented by the chemical formula Mg_{3.2}Sb_{1.6}Bi_{0.38-c}C_{c}Te_{0.01} were fabricated in similar ways to those of the inventive examples 1-3. In the present examples, C is Cr. The value of c of each of the provided Zintl-phase thermoelectric conversion materials was 0.9-1.1 times as high as that of the starting composition.

Table 13 shows the element C, the value of c, the average grain size, and the thermoelectric conversion performance index ZT at a temperature of 200 degrees Celsius of the present inventive examples and comparative examples. In Table 13, note that C is Cr. The thermoelectric conversion performance index ZT at a temperature of 200 degrees Celsius is significantly improved, when the following requirements (I) and (II) are satisfied.

(I) the value of c is not less than 0 and not more than 0.1.

(II) the average grain size is approximately not less than 3 micrometers and not more than 70 micrometers.

On the other hand, when the value of c is more than 0.1, the thermoelectric conversion performance index ZT at a temperature of 200 degrees Celsius is low, regardless of the value of the average grain size.

TABLE 13

| | | | | Thermoelectric |
|---|---|---|---|---|
| | | | | conversion performance |
| | | | | index ZT at a |
| | | | | temperature of |
| | Element C | Value of c | Grain Size | 200 degrees Celsius |
| C.E. 46A | None | 0 | 1.3 | 0.2 |
| I.E. 36A | None | 0 | 4.6 | 0.8 |
| I.E. 36B | None | 0 | 27.2 | 0.8 |
| I.E. 36C | None | 0 | 66.4 | 0.6 |
| C.E. 46B | None | 0 | 86.8 | 0.3 |
| C.E. 47A | Cr | 0.05 | 1.4 | 0.2 |
| I.E. 37A | Cr | 0.05 | 3.3 | 0.9 |
| I.E. 37B | Cr | 0.05 | 28.6 | 0.8 |
| I.E. 37C | Cr | 0.05 | 63.5 | 0.7 |
| C.E. 47B | Cr | 0.05 | 89.9 | 0.3 |
| C.E. 48A | Cr | 0.1 | 1.5 | 0.1 |
| I.E. 38A | Cr | 0.1 | 3.8 | 0.7 |
| I.E. 38B | Cr | 0.1 | 31.2 | 0.7 |
| I.E. 38C | Cr | 0.1 | 68.7 | 0.5 |
| C.E. 48B | Cr | 0.1 | 86.6 | 0.2 |
| C.E. 49A | Cr | 0.15 | 3.8 | 0.3 |
| C.E. 49B | Cr | 0.15 | 22.3 | 0.2 |

### INDUSTRIAL APPLICABILITY

The Zintl-phase thermoelectric conversion material according to the present invention has a high thermoelectric conversion performance index at a temperature of approximately 200 degrees Celsius. Therefore, the Zintl-phase thermoelectric conversion material according to the present invention is useful for a thermoelectric module capable of generating electric power using exhaust heat having a temperature of 200-300 degrees Celsius.

1. A thermoelectric conversion material represented by the following chemical formula (I):
Mg₃₊ₘ₋ₐAₐB_{2-c-e}C_{c}Eₑ (I)
where
the element A represents at least one selected from the group consisting of Ca, Sr, Ba, Nb, Zn, and Al;
the element B represents at least one selected from the group consisting of Sb and Bi;
the element C represents at least one selected from the group consisting of Mn, Si, and Cr;
the element E represents at least one selected from the group consisting of Se and Te;
the value of m is not less than −0.1 and not more than 0.4;
the value of a is not less than 0 and not more than 0.1;
the value of c is not less than 0 and not more than 0.1;
the value of e is not less than 0.001 and not more than 0.06;
the thermoelectric conversion material has a La₂O₃ crystal structure; and
the thermoelectric conversion material has an average grain size of not less than 3 micrometers and not more than 70 micrometers.

2. The thermoelectric conversion material according to claim 1, wherein
the value of m is not less than −0.05 and not more than 0.3;
the value of a is 0;
the value of c is 0;
the value of e is not less than 0.005 and not more than 0.03; and
the thermoelectric conversion material has an average grain size of not less than 3 micrometers and not more than 30 micrometers.
